(19) United States
(12) Patent Application Publication
(10) Pub. No.: US 2013/0284213 A1
(43) Pub. Date: Oct. 31, 2013

(54) SUBSTRATE PROCESSING APPARATUS AND SUBSTRATE PROCESSING METHOD

(71) Applicant: TOKYO ELECTRON LIMITED, Tokyo (JP)

(72) Inventors: Yosuke Hachiya, Kumamoto (JP); Norihiro Ito, Kumamoto (JP); Hisashi Kawano, Kumamoto (JP); Jun Nonaka, Kumamoto (JP); Jun Nogami, Kumamoto (JP)

(73) Assignee: Tokyo Electron Limited, Tokyo (JP)

(21) Appl. No.: 13/858,248

(22) Filed: Apr. 8, 2013

(30) Foreign Application Priority Data
Apr. 26, 2012 (JP) 2012-101613
Sep. 24, 2012 (JP) 2012-210029

(51) Int. Cl. H01L 21/02

(52) U.S. Cl. CPC H01L 21/02076
USPC 134/36; 134/100.1; 134/102.1

(57) ABSTRACT

The present disclosure provides a substrate processing method and a substrate processing apparatus. The substrate processing method includes: generating an SPM liquid of a first temperature that contains Caro's acid having a separation effect of a resist film formed on the surface of a substrate by mixing heated sulfuric acid with hydrogen peroxide; cooling the SPM liquid to a second temperature at which a reduction effect of film loss occurs; and applying the SPM liquid of the second temperature to the resist film thereby separating the resist film.

### CROSS-REFERENCE TO RELATED APPLICATIONS

This application is based on and claims priorities from Japanese Patent Application Nos. 2012-101613 and 2012-210029, filed on Apr. 26, 2012 and Sep. 24, 2012, respectively, with the Japan Patent Office, the disclosures of which are incorporated herein in their entireties by reference.

### TECHNICAL FIELD

The present disclosure relates to a technology that removes a resist film formed on the surface of a substrate.

### BACKGROUND

In a manufacturing process of a semiconductor device, a predetermined pattern of resist film is formed on a film to be processed (“target film”) formed on a substrate such as, for example, a semiconductor wafer (“wafer”), and a processing such as, for example, an etching and an ion implantation is performed on the target film using the resist film as a mask. After the processing, the resist film that is not necessary any more is removed on the wafer. An SPM (sulfuric acid hydrogen peroxide mixture) processing has often been used as a removing method of the resist film. The SPM processing is performed by supplying a hot SPM liquid, which is obtained by mixing sulfuric acid with hydrogen peroxide, to the resist film.

The resist film provided as a mask for the ion implantation includes a hardened layer on the surface thereof, and there has been a problem to remove the resist film effectively by the SPM processing. Japanese Patent Application Laid-Open No. 2008-4878 discloses one of methods to solve the problem. In the technology disclosed in Japanese Patent Application Laid-Open No. 2008-4878, a separation efficiency of the resist film is improved by (1) softening the surface hardened layer of a wafer by heating the wafer to a high temperature about 200 to 250 by a heater built in a spin chuck and (2) destroying the surface hardened layer effectively by colliding a mixed fluid, having a high physical energy and composed of N₂ gas and mists of SPM liquid (having a temperature that does not decrease the wafer temperature), with the resist film. The mixed fluid is formed by joining the N₂ gas with the SPM liquid sprayed from a nozzle.

When the SPM liquid that does not decrease the wafer temperature is supplied to the wafer heated to a high temperature about 200 to 250, it is considered that the SPM liquid is reacted under a significantly high temperature. In such a circumstance, it has been found out that the removal efficiency of the resist film may be increased. However, a film loss (which indicates that a valuable film such as, for example, a SiO₂ film and a SiN film which are presented below the resist film is peeled by the SPM liquid) may be significantly increased as well.

### SUMMARY

The present disclosure provides a substrate processing method including: generating an SPM liquid of a first temperature that contains Caro's acid (peroxysulfuric acid) having a separation effect of a resist film formed on the surface of a substrate by mixing heated sulfuric acid with hydrogen peroxide; cooling the SPM liquid to a second temperature at which a reduction effect of film loss occurs; and applying the SPM liquid of the second temperature to the resist film thereby separating the resist film.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a vertical cross-sectional view schematically illustrating the configuration of a substrate processing apparatus according to a first exemplary embodiment of the present disclosure.

FIG. 2 is a schematic plan view of the substrate processing apparatus illustrated in FIG. 1.

FIG. 3 is a cross-sectional view taken along line III-III in FIGS. 2 and 4, which illustrates the configuration in the vicinity of a discharging port of a first rod shaped nozzle unit of the substrate processing apparatus in FIG. 1.

FIG. 4 is a bottom view of the first rod shaped nozzle unit.

FIG. 5 is a schematic view illustrating the configuration of a deionized water supply unit and the structure of a second rod shaped nozzle unit as illustrated in FIG. 2.

FIG. 6 is a view describing a second exemplary embodiment of the present disclosure, which schematically illustrates the configuration of a twin fluid supply unit that supplies a DIW+N₂ twin fluid to the first rod shaped nozzle unit.

FIG. 7 is a view describing a third exemplary embodiment of the present disclosure, which is a cross-sectional view of the first rod shaped nozzle unit configured to cause N₂ gas, SPM liquid and DIW discharged individually to be joined before reaching the wafer.

FIG. 8 is a schematic view illustrating the configuration of a substrate processing apparatus according to a fourth exemplary embodiment of the present disclosure.

FIG. 9 is a cross-sectional view schematically illustrating a cooling device of the substrate processing apparatus illustrated in FIG. 8.

FIG. 10 is a schematic view describing a modified embodiment which is applicable to the first to fourth exemplary embodiments of the present disclosure.

FIGS. 11A and 11B are cross-sectional views of a first nozzle unit at the same position as in FIG. 3, which describe modified embodiments of the first to third exemplary embodiments, respectively.

FIG. 12 is a vertically cross-sectional view illustrating the configuration of a twin fluid nozzle used in fifth and sixth exemplary embodiments of the present disclosure.

FIG. 13 is a bottom view of the twin fluid nozzle illustrated in FIG. 12.

FIG. 14 is a cross-sectional view taken along line XIV-XIV in FIG. 12.

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made, without departing from the spirit or scope of the subject matter presented here.

In the SPM processing, the reduction of a film loss as possible and the effective removal of a resist film are concurrently required. The present disclosure is to provide an SPM processing technology which is capable of achieving the improvement of the removal efficiency of a resist film and the reduction of a film loss.

The present disclosure provides a substrate processing method including: generating an SPM liquid of a first temperature that contains Caro's acid having a separation effect of a resist film formed on the surface of a substrate by mixing heated sulfuric acid with hydrogen peroxide; cooling the SPM liquid to a second temperature at which a reduction effect of film loss occurs; and applying the SPM liquid of the second temperature to the resist film thereby separating the resist film.

In the above-described substrate processing method, the cooling step may be performed by mixing the SPM liquid with N₂ gas that flows toward the substrate.

In the above-described substrate processing method, the cooling step may be performed by mixing deionized water and the SPM liquid with the N₂ gas that flows toward the substrate.

In the above-described substrate processing method, the cooling step may be performed by mixing the SPM liquid with a twin fluid composed by mixing droplets of the deionized water with N₂ gas and flowing toward the substrate.

In the above-described substrate processing method, the cooling step may be performed using a cooler provided in a pipe between a position where the sulfuric acid and the hydrogen peroxide are mixed and a nozzle that discharges the SPM liquid to the substrate.

In the above-described substrate processing method, the SPM liquid cooled to the second temperature may be supplied to the substrate in a state where a liquid film of water is formed on the surface of the substrate.

Further, the present disclosure provides a substrate processing apparatus that removes a resist film formed on the surface of a substrate. The substrate processing apparatus may include: a substrate holding unit configured to hold the substrate; a sulfuric acid supply unit to configured to supply sulfuric acid; a hydrogen peroxide supply unit configured to supply hydrogen peroxide; a mixing unit configured to mix the sulfuric acid supplied from the sulfuric acid supply unit with the hydrogen peroxide supplied from the hydrogen peroxide supply unit to generate an SPM liquid; an SPM liquid supply unit configured to supply the SPM liquid to the substrate; and a cooling unit configured to cool the SPM liquid of a first temperature which is flown out from the mixing unit and contains Caro's acid having a separation effect of the resist film to a second temperature at which a reduction effect of film loss occurs before the SPM liquid reaches the substrate.

In the above-described substrate processing apparatus, the cooling unit may include a cooling fluid discharging unit configured to discharge cooling fluid that is capable of cooling the SPM liquid toward the substrate, and the SPM liquid supply unit may include a joining unit configured to cause the flow of the SPM liquid to join the flow of the cooling fluid before the cooling fluid reaches the surface of the substrate.

In the above-described substrate processing apparatus, the joining unit that causes the flow of the SPM liquid to join the flow of the cooling fluid may include a chemical liquid nozzle configured to discharge the SPM liquid toward the substrate, the cooling fluid discharging unit may include a gas nozzle configured to discharge N₂ gas toward the substrate, and the gas nozzle may be configured such that the N₂ gas discharged from the gas nozzle is mixed with the SPM liquid discharged from the chemical liquid nozzle before the SPM liquid reaches the substrate.

In the above-described substrate processing apparatus, the joining unit that causes the flow of the SPM liquid to join the flow of the cooling fluid may include a chemical liquid nozzle configured to discharge the SPM liquid toward the substrate, the cooling fluid discharging unit may include a gas nozzle configured to discharge N₂ gas toward the substrate and a deionized water nozzle configured to discharge deionized water toward the substrate, the gas nozzle may be configured such that the N₂ gas discharged from the gas nozzle is mixed with the SPM liquid discharged from the chemical liquid nozzle before the SPM liquid reaches the substrate, and the deionized water nozzle may be configured such that the deionized water discharged from the deionized water nozzle is mixed with the SPM liquid discharged from the chemical liquid nozzle before the SPM liquid reaches the substrate.

In the above-described substrate processing apparatus, the joining unit that causes the flow of the SPM liquid to join the flow of the cooling fluid may include a chemical liquid nozzle configured to supply the SPM liquid toward the substrate, the cooling fluid discharging unit may include a twin fluid nozzle configured to discharge twin fluid composed by mixing the droplets of the deionized water with the N₂ gas toward the substrate, and the twin fluid nozzle may be configured such that the twin fluid discharged from the twin fluid nozzle is mixed with the SPM liquid discharged from the chemical liquid nozzle before the SPM liquid reaches the substrate.

In the above-described substrate processing apparatus, the SPM liquid supply unit may include a chemical liquid nozzle configured to supply the SPM liquid toward the substrate, and the cooling unit may include a cooler provided in the pipe that causes the SPM liquid to flow from the mixing unit to the chemical liquid nozzle.

The above-described substrate processing apparatus may further include a deionized water nozzle configured to supply deionized water to the substrate, and a control unit configured to control the operations of the substrate processing apparatus such that, when the deionized water is supplied from the deionized water nozzle to form a liquid film of the deionized water on the surface of the substrate, the SPM liquid supplied by the SPM liquid supply unit and cooled by the cooling unit is discharged toward the substrate.

According to the present disclosure, by cooling the SPM liquid of the first temperature that sufficiently contains Caro's acid having a separation effect of a resist film to the second temperature at which a reduction effect of film loss occurs, the SPM liquid with relatively high Caro's acid concentration and relatively low temperature may be in contact with the substrate. Accordingly, high removal efficiency of the resist film may be achieved and the film loss may be reduced.

Hereinafter, the configuration of a substrate processing apparatus according to exemplary embodiments of the present disclosure will be described with reference to the drawings.

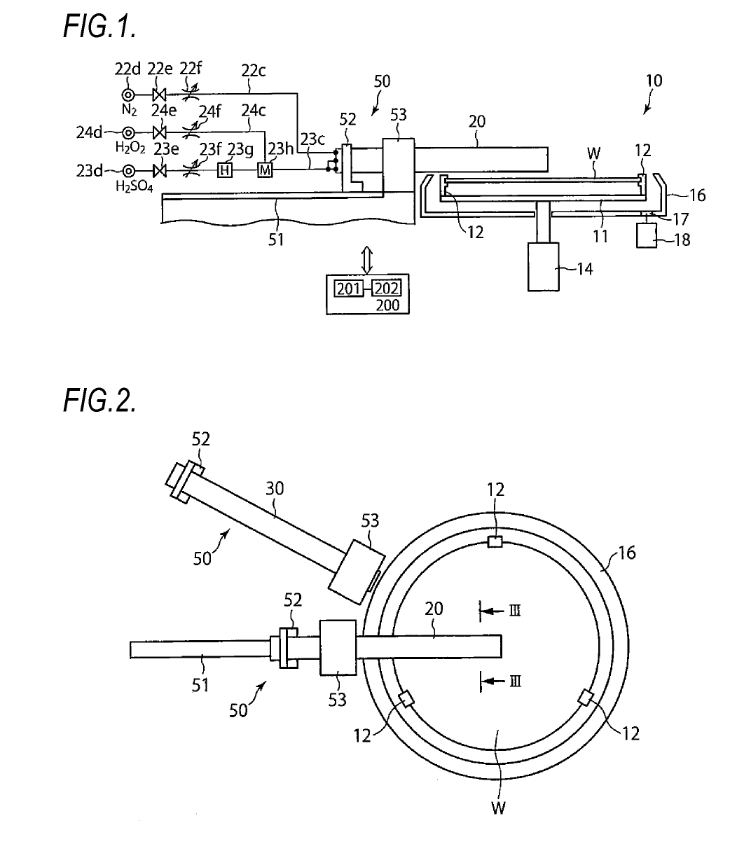

A first exemplary embodiment will be described with reference to FIGS. 1 to 5. A substrate processing apparatus 10 includes a substrate holding unit 11 configured to hold a semiconductor wafer W (“wafer W”) horizontally and rotate the wafer about a vertical axis. Substrate holding unit 11 includes a plurality of, for example, three grasp claws (substrate holding members) 12 that grasp the peripheral portion of wafer W. At least one grasp claw is actuated to switch between the grasp and the release of wafer W. Substrate holding unit 11 may rotate about the vertical axis by a driving mechanism 14 provided therebelow. Also, driving mechanism 14 has a function to ascend/descend substrate holding unit 11.

A cup 16 is provided to surround the circumference of substrate holding unit 11. Cup 16 is configured to receive a processing liquid which is supplied to rotating wafer W and scattered from wafer W outwardly by centrifugal force and not to scatter the processing liquid to the surrounding space. A discharging port 17 that discharges the processing liquid and reaction products to the outside of cup 16 is provided in the bottom portion of cup 16. Exhaust/drain means such as, for example, a mist trap and an ejector, which is schematically indicated by a box with a reference numeral of 18, is connected to discharging port 17.

A first rod shaped nozzle unit 20 and a second rod shaped nozzle unit 30 are provided in the outside of cup 16. First rod shaped nozzle unit 20 may move in a nozzle lengthwise direction by a straight moving mechanism 50. That is, first rod shaped nozzle unit 20 may be located at an advance position (processing position) where the front side of first rod shaped nozzle unit 20 is located above wafer W held by substrate holding unit 11 and a retreat position (stand-by position) where the entirety of first rod shaped nozzle unit 20 is located in the outside of the cup when viewed from the above. Second rod shaped nozzle unit 30 also includes a straight moving mechanism 50 and may move as in first rod shaped nozzle unit 20. FIG. 2 illustrates a situation where first rod shaped nozzle unit 20 is located in the advance position and second rod shaped nozzle unit 30 is located in the retreat position.

Straight moving mechanism 50 includes a linear guide 51, a pulley/belt driving mechanism (not illustrated in the drawing) provided below linear guide 51, a nozzle holding body 52 that is fixed to a belt of the pulley/belt driving mechanism and holds the rear end of first rod shaped nozzle unit 20, and a support body 53 that holds first rod shaped nozzle unit 20 to be slidable. By driving the pulley/belt driving mechanism, nozzle holding body 52 may move along linear guide 51 to advance/retreat first rod shaped nozzle unit 20. A nozzle cleaning device may be embedded in support body 53.

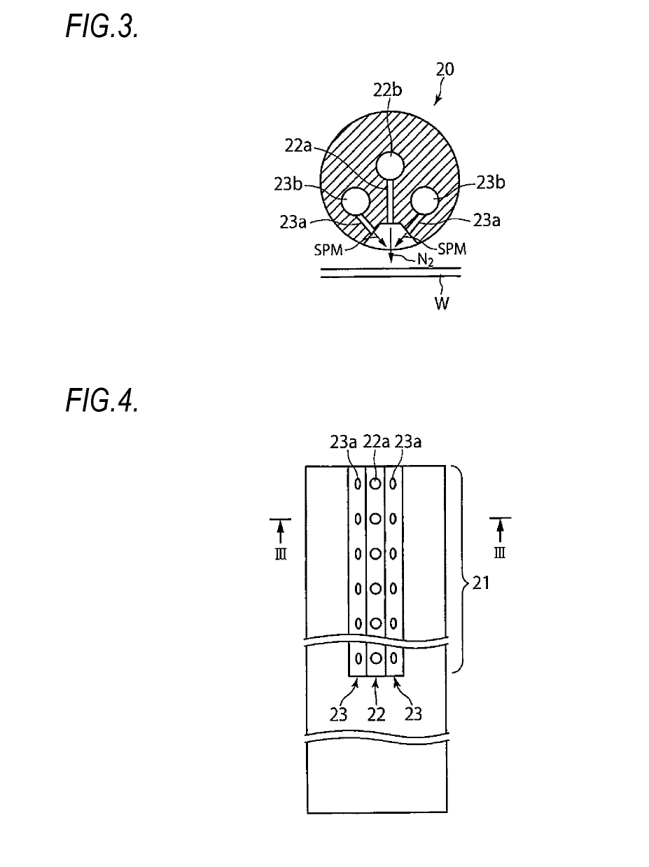

Next, the configuration of first rod shaped nozzle unit 20 will be described with reference to FIGS. 3 and 4. First rod shaped nozzle unit 20 is configured in a combination of a first nozzle part 22 configured to discharge N₂ gas (nitrogen gas) and second nozzle parts 23 provided in the both side of first nozzle part 22 and configured to mainly discharge SPM liquid.

A processing fluid discharging part 21 is provided in a range from the front end of first rod shaped nozzle unit 20 to a position that is spaced apart from the front end by a predetermined distance (which roughly corresponds to a radius of wafer W). A plurality of gas discharging ports 22a and a plurality of chemical liquid discharging ports 23a are formed in processing fluid discharging part 21. Plurality of gas discharging ports 22a are arranged while being spaced apart from each other along the lengthwise direction of first rod shaped nozzle unit 20. Plurality of chemical liquid discharging ports 23a are arranged while being spaced apart from each other along the lengthwise direction of first rod shaped nozzle unit 20. One gas discharging port 22a and two chemical liquid discharging ports 23a are formed in the same lengthwise positions of first rod shaped nozzle unit 20, respectively. Gas discharging port 22a located in the most front end side of first rod shaped nozzle unit 20 may be formed such that it is located just above the center of wafer W when first rod shaped nozzle unit 20 is located at the advance position.

First nozzle part 22 is constituted by a portion of first rod shaped nozzle unit 20 where plurality of gas discharging ports 22a as described above are formed, and second nozzle parts 23 are constituted by portions of first rod shaped nozzle unit 20 where plurality of chemical liquid discharging ports 23a are formed, respectively.

As illustrated in FIG. 3, discharging ports 22a and 23a are configured such that flows of SPM liquids discharged downward to be inclined from two chemical liquid discharging ports 23a provided in the both side of one gas discharging port 22a join flow of N₂ gas discharged downward perpendicularly to the surface of wafer W from one gas discharging port 22a, when the N₂ gas and the SPM liquid are concurrently discharged from gas discharging port 22a and chemical liquid discharging ports 23a. By joining the SPM liquid with the high-pressured flow of the N₂ gas, the SPM liquid is cooled, and at the same time, a mixed fluid composed of droplets (mists) of the SPM liquid and the N₂ gas is generated. Further, as illustrated, a plurality of (two in the present example) flows of the SPM liquid are collided on the extension of the axis of gas discharging port 22a, and thus, the SPM liquid may be effectively formed into mists. However, a flow of the SPM liquid discharged from one chemical liquid discharging port may join the flow of the N₂ gas discharged from one gas discharging port.

A single gas distribution passage 22b is formed within first rod shaped nozzle unit 20, which extends from the base end of first rod shaped nozzle unit 20 to a position right ahead of the front end of first rod shaped nozzle unit 20. A plurality of gas discharging ports 22a are connected to gas distribution passage 22b, as illustrated in FIG. 3. Two chemical liquid distribution passages 23b that extend from the base end of first rod shaped nozzle unit 20 to a position right ahead of the front end of first rod shaped nozzle unit 20 in parallel to gas distribution passage 22b are also formed within first rod shaped nozzle unit 20. A plurality of chemical liquid discharging ports 23a arranged in one side of first rod shaped nozzle unit 20 (in the left side of FIGS. 3 and 4) are connected to one chemical liquid distribution passage 23b, and a plurality of chemical liquid discharging ports 23a arranged in the other side of first rod shaped nozzle unit 20 (in the right side of FIGS. 3 and 4) are connected to the other chemical liquid distribution passage 23b.

As illustrated in FIG. 1, a gas line 22c composed of, such as for example, a pipe is connected to gas distribution passage 22b of first rod shaped nozzle unit 20. The base end of gas line 22c is connected to an N₂ gas supply source 22d that supplies a pressurized N₂ gas at room temperature. The temperature of the N₂ gas is not limited to the room temperature, but the temperature may be a low temperature as possible. An opening/closing valve 22e and a flow control valve 22f are interposed and provided on gas line 22c. An N₂ gas supply unit is configured by gas line 22c and various devices such as, e.g., 22d, 22e, 22f which are provided therein. In an appropriately one exemplary embodiment (not limited thereto), the N₂ gas is supplied under a pressure of about 0.2 MPa to 0.3 MPa.

A chemical liquid line 23c composed of, such as for example, a pipe is connected to chemical liquid distribution passages 23b of first rod shaped nozzle unit 20. The base end of chemical liquid line 23c is connected to a sulfuric acid supply source 23d composed by, for example, a tank that stores sulfuric acid. An opening/closing valve 23e, a flow control valve 23f and a heater 23g that heats the sulfuric acid are interposed and provided in this order on chemical liquid line 23c. A mixer 23h (mixing unit) is also interposed and provided on chemical liquid line 23c. A separate chemical liquid line 24c is connected to mixer 23h, and the base end of chemical liquid line 24c is connected to a hydrogen peroxide supply source 24d composed by, for example, a tank that stores the hydrogen peroxide. An opening/closing valve 24e and a flow control valve 24f are interposed and provided on chemical liquid line 24c. In mixer 23h, the sulfuric acid from chemical liquid line 23c and the hydrogen peroxide from chemical liquid line 24c are evenly mixed, thereby generating SPM liquid. The sulfuric acid supply unit is configured by chemical liquid line 23c and various devices 23d to 23g which are provided therein, the hydrogen peroxide supply unit is configured by chemical liquid line 24c and various devices 24d to 24f which are provided therein, and the SPM liquid supply unit is configured by the sulfuric acid supply unit, the hydrogen peroxide supply unit, and mixer 23h.

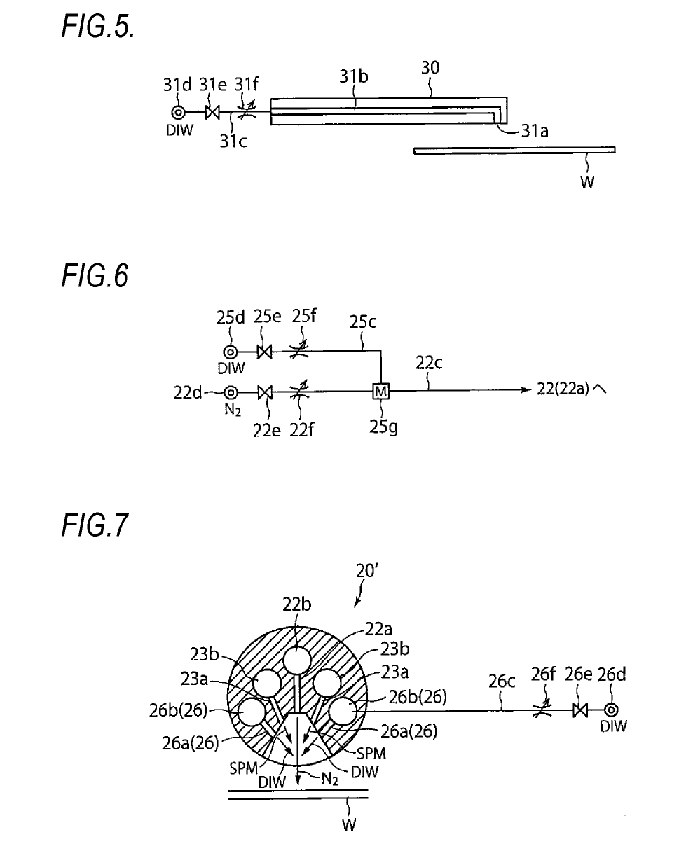

Next, the configuration of second rod shaped nozzle unit 30 will be simply described with reference to FIG. 5. Second rod shaped nozzle unit 30 is constituted by a single rinse nozzle, and has a single rinse liquid discharging port 31a at the front end thereof. A rinse liquid passage 31b is formed within second rod shaped nozzle unit 30, and a rinse liquid line 31c is connected to rinse liquid passage 31b. The base end of rinse liquid line 31c is connected to a deionized water (DIW) supply source 31d as the rinse liquid, and an opening/closing valve 31e and a flow control valve 31f are interposed and provided on rinse liquid line 31c. A rinse liquid supply unit is configured by rinse liquid line 31c and various devices such as, e.g., 31d, 31e, 31f which are provided therein.

As schematically illustrated in FIG. 1, substrate processing apparatus 10 includes a controller 200 that integrally controls the entire operations thereof. Controller 200 controls the operations of all of the functional components (for example, substrate holding unit 11, driving mechanism 14, and various valves). Controller 200 may be implemented using, for example, a general purpose computer as a hardware and a program (an apparatus control program and a processing recipe) to operate the computer as a software. The software may be stored on a storage medium such as, for example, a hard disc drive which is fixedly provided in the computer, or on a storage medium such as, for example, a CD-ROM, a DVD, and a flash memory which is removably set in the computer. The storage medium is indicated by a reference numeral 201 in FIG. 1. A processor 202 calls and executes a predetermined processing recipe from a storage medium 201 based on, for example, instructions from a user interface (not illustrated) as needed, and as a result, each functional component of substrate processing apparatus 10 is operated under the control of controller 200 to perform a predetermined processing.

Next, a series of processes of a cleaning will be described. The cleaning removes unnecessary resist film on the top surface of wafer W, especially high dose resist film having a hardened layer on the surface thereof by an ion implantation using substrate processing apparatus 10 as described above. Controller 200 controls the operations of respective functional components of substrate processing apparatus 10 such that the series of processes of the cleaning as described below are performed.

First, substrate holding unit 11 is raised by driving mechanism 14 while first and second rod shaped nozzle units 20, 30 are stand-by in their retreat positions, respectively. Wafer W having an unnecessary resist film to be removed on the surface thereof is carried in to a position of substrate holding unit 11 from the outside of substrate processing apparatus 10 by a transport arm (not illustrated). When wafer W is held by grasp claws 12, the transport arm (not illustrated) is retreated. Then, substrate holding unit 11 descends to accommodate wafer W within cup 16.

[SPM Processing]

Next, first rod shaped nozzle unit 20 moves to the advance position, and wafer W is rotated by driving mechanism 14. In such a state, the N₂ gas supply unit and the SPM liquid supply unit are driven to discharge N₂ gas from gas discharging port 22a and discharge SPM liquid from chemical liquid discharging ports 23a, respectively, as illustrated by arrows in FIG. 3. The N₂ gas and the SPM liquid are mixed before reaching wafer W, the unnecessary resist film of the surface of wafer W is separated by the mixed fluid. The separated resist film is outputted to the outside of wafer along with the SPM liquid that flows toward the outside of wafer by centrifugal force. The SPM processing details will be described as below.

[Rinse Processing]

After the above-described SPM processing was performed in a predetermined time period, the discharges of the N₂ gas and the SPM liquid stopped, and first rod shaped nozzle unit 20 moves to the retreat position. Then, second rod shaped nozzle unit 30 moves to the advance position, and rinse liquid discharging port 31a is located just above the rotation center of wafer W. Then, the rinse liquid supply unit is driven to supply the DIW as the rinse liquid to the wafer. For example, the SPM liquid, the resist residue, and the reaction product that remain on the surface of wafer W are flowed out to the outside of wafer W together with the DIW that flows to the outside of wafer by the centrifugal force.

[Spin Dry Processing]

After the DIW rinse processing was performed in a predetermined time period, the discharge of the DIW from rinse liquid discharging port 31a stops, and second rod shaped nozzle unit 30 moves to the retreat position. Then, the DIW on the surface of wafer W is thrown off to dry wafer W by increasing the rotation speed of wafer W. As a result, a series of liquid processing for a single wafer W is completed. Then, the processed wafer W is carried out from substrate processing apparatus 10 in a reverse procedure of the carrying-in of wafer W as described above.

Next, the SPM processing details will be described.

The temperature of the SPM liquid is one of factors that affect the resist separation ability of the SPM liquid. We found that, when the temperature of the SPM liquid is raised, the resist separation ability is increased, but the film loss is increased. Further, the temperature of the SPM liquid when the liquid exists on the wafer affects the separation ability and the film loss, and the film loss is considerably increased even though the wafer temperature is increased by the heating means such as, for example, a heater as described above. Therefore, in order to reduce the film loss, it is needed that the temperature of the SPM liquid on the wafer is lowered.

The concentration of the Caro's acid (H₂SO₅) within the SPM liquid is another factor that greatly affects the resist separation ability of the SPM liquid. The Caro's acid is generated based on a reaction formula “H₂SO₄+H₂O₂→H₂SO₅+H₂O” by mixing Sulfuric acid with Hydrogen peroxide. The Caro's acid generating reaction is an endothermic reaction. However, when the sulfuric acid and the hydrogen peroxide are mixed, a heat of hydration occurs, too. The higher the concentration of the Caro's acid, the higher the resist separation ability of the SPM liquid. The concentration of the Caro's acid is increased as time elapses after mixing the sulfuric acid with the hydrogen peroxide. After reaching the peak thereof, the concentration becomes gradually lowered by the decomposition of the Caro's acid.

Considering the above description, in the present exemplary embodiment, heated sulfuric acid and hydrogen peroxide are mixed to generate an SPM liquid of a first temperature (e.g., 180) with a resist film separation effect. Here, “with a resist film separation effect” refers that the Caro's acid which is sufficient to have a removal effect of the resist film is generated and included within the SPM liquid. Then, the SPM liquid is cooled (to a second temperature (e.g., 150)). And, the SPM liquid of the second temperature is supplied to the surface of the wafer. In order to lower the temperature, specifically, the SPM liquid is discharged from the chemical liquid nozzle after the Caro's acid is sufficiently generated, the discharged SPM liquid joins the flow of the N₂ gas discharged from the gas nozzle. Therefore, the SPM liquid is cooled by the N₂ gas. The SPM liquid is deprived of the heat to the N₂ gas by contacting the N₂ gas. Further, the SPM liquid is formed into mists and thus, the surface area of the SPM liquid is rapidly increased. Therefore, the temperature of the SPM liquid is lowered by the heat dissipation from each droplet to the surrounding atmosphere. As a result, since the temperature of the SPM liquid is capable of being lowered while maintaining a state where the concentration of the Caro's acid is sufficiently increased, the resist film may be effectively separated and removed as well as the film loss may be suppressed. Further, a path distance from mixer 23h which is a mixing point of the sulfuric acid and the hydrogen peroxide to chemical liquid discharging port 23a may be set to a value where the sufficient reaction time for the generation of the Caro's acid is ensured, and may be set to a value where the concentration or amount of the Caro's acid reaches the peak right before the decomposition of the Caro's acid included in the SPM liquid, after the SPM liquid is discharged from chemical liquid discharging port 23a (just before the SPM liquid reaches the wafer). Since the optimal value of the path distance is changed based on the configuration of the apparatus and the changes of the various conditions such as, for example, flow rates, temperatures and concentrations of the sulfuric acid and the hydrogen peroxide, the path distance where the SPM liquid is capable of reaching wafer W at the timing when the concentration of the Caro's acid within the SPM liquid reaches the peak and the supply conditions of the sulfuric peroxide/hydrogen peroxide may be determined based on the experiments.

Further, in the present exemplary embodiment, the SPM liquid joins the flow of the pressurized N₂ gas and the SPM liquid is formed into the droplets (mists), and as a result, a twin fluid (mixed fluid) composed of the SPM mists and the N₂ gas is formed. By the high physical energy of the twin fluid, the hardened surface layer of the resist film may be cracked to facilitate the separation of the resist film.

Further, in the above-described first exemplary embodiment, the cooling of the SPM liquid is performed using the N₂ gas, but the present disclosure is not limited thereto. As a second exemplary embodiment, the cooling of the SPM liquid may be performed using a twin fluid which is formed by mixing the droplets of the deionized water (DIW) with the N₂ gas. In the second exemplary embodiment, a DIW supply unit as illustrated in FIG. 6 may be provided in a fluid line (gas line 22c) that supplies the fluid (N₂ gas) to the discharging port (gas discharging port 22a) of first nozzle part 22 in the first exemplary embodiment. Specifically, a mixer 25g is provided in the fluid line (gas line 22c), and a DIW line 25c connected to a DIW supply source 25d is connected to mixer 25g. An opening/closing valve 25e and a flow control valve 25f are provided in DIW line 25c. Other configuration may be the same as in the first exemplary embodiment. According to the configuration of the second exemplary embodiment, DIW introduced into mixer 25g with a controlled flow rate from DIW supply source 25d is mixed with the N₂ gas introduced into mixer 25g with a controlled flow rate from N₂ gas supply source 22d in mixer 25g to be formed into a smog, and the twin fluid composed by mixing the mists (droplets) of the DIW with the N₂ gas is discharged from the discharging port (gas discharging port 22a) of first nozzle part 22. The twin fluid joins the SPM liquid discharged from chemical liquid discharging ports 23a, the SPM liquid is cooled by mixing the twin fluid with the SPM liquid, and then, the mixed fluid reaches the surface of wafer W. Therefore, an effect which is roughly same as in the first exemplary embodiment as described above may be obtained. However, when the DIW is mixed with the SPM liquid, some hydration heats may occur. Therefore, in order to surely lower the temperature of the SPM liquid by causing an effect where the DIW deprives heat from the SPM liquid to exceed an effect where the hydration heat increases the temperature of the SPM liquid, the temperature of the DIW may be lowered and the DIW may be supplied at a temperature that is equal to or less than a room temperature. Further, the DIW becomes easy to evaporate by being formed into a smog, some of the DIW are evaporated, and thus, the temperature of the twin fluid composed of the DIW and the N₂ (temperature just before mixing with the SPM liquid) is lowered by the evaporation heat. Therefore, in order to supply a DIW with a lower temperature, the supply conditions (for example, mixing ratio and flow rate) of the DIW and the N₂ gas may be determined such that the DIW is favorably formed into smog. Further, in the present exemplary embodiment, a twin fluid rinsing may be performed by stopping the discharging of the SPM liquid and supplying only the twin fluid composed of the DIW mists and the N₂ gas to wafer W, after the SPM liquid processing is completed.

In addition, as for a third exemplary embodiment, the cooling of the SPM liquid may be performed using the N₂ gas and the DIW which are discharged separately. In the third exemplary embodiment, with respect to first rod shaped nozzle unit 20 of the first exemplary embodiment, a first rod shaped nozzle unit 20′ is used, in which a third nozzle part 26 to discharge DIW is combined thereto. The other configurations may be the same as in the first exemplary embodiment. Specifically, as illustrated in FIG. 7, a plurality of DIW discharging ports 26a are formed in first rod shaped nozzle unit 20′ such that the ports are arranged in two rows which extend in the lengthwise direction of first rod shaped nozzle unit 20′. The plurality of DIW discharging ports 26a are arranged to be spaced apart from each other along the lengthwise direction of first rod shaped nozzle unit 20′. A single gas discharging port 22a, two chemical liquid discharging ports 23a, and two DIW discharging ports 26a are formed in the same positions in the lengthwise direction of first rod shaped nozzle unit 20′. Two DIW distribution passages 26b are formed within first rod shaped nozzle unit 20′, which extend in the lengthwise direction thereof. A plurality of DIW discharging ports 26a in one side of first rod shaped nozzle unit 20′ are connected to one DIW distribution passage 26b, and a plurality of DIW discharging ports 26a in the other side of first rod shaped nozzle unit 20′ are connected to the other DIW distribution passage 26b. A DIW line 26c composed of, for example, a pipe is connected to DIW distribution passages 26b of first rod shaped nozzle unit 20′. The base end of DIW line 26c is connected to a DIW supply source 26d that supplies DIW. An opening/closing valve 26e and a flow control valve 26f are interposed and provided on DIW line 26c. A DIW supply unit is configured by DIW line 26c and various devices, for example, 26d, 26e, 26f provided therein. In the third exemplary embodiment, the flows of the SPM liquid discharged slantly and downwardly from two chemical liquid discharging ports 23a join the flow of the N₂ gas discharged vertically and downwardly from one gas discharging port 22a to the surface of wafer W, and the flows of the DIW discharged slantly and downwardly from two DIW discharging ports 26a further join the joined flow, and then, the finally joined flow is collided with wafer W. Therefore, in the third exemplary embodiment, an effect that is roughly same as in the second exemplary embodiment may be obtained. Further, in the third exemplary embodiment, based on the reason that is the same as in the description in the second exemplary embodiment, the temperature of the DIW may be further lowered, and the DIW may be supplied at a temperature equal to or less than the room temperature.

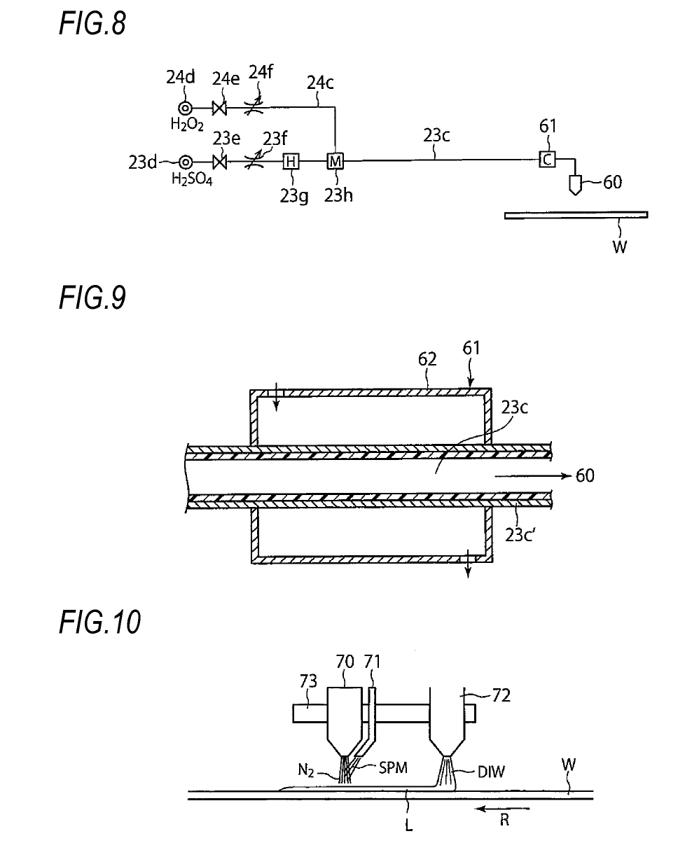

In the first to third exemplary embodiments, the SPM liquid is cooled by joining the SPM liquid and a cooling fluid (N₂ gas, and DIW), but the present disclosure is not limited thereto. As a fourth exemplary embodiment, the SPM liquid may be cooled by a cooling device before the SPM liquid is discharged. Specifically, as illustrated in FIG. 8, a cooler 61 may be provided on chemical liquid line 23c between mixer 23h and a nozzle 60. Cooler 61 may be provided in a position that is sufficiently spaced apart from mixer 23h, for example, the vicinity of nozzle 60 such that the SPM liquid is cooled after a sufficient amount of Caro's acid is generated in the SPM liquid. For example, as illustrated in FIG. 9, cooler 61 may be configured by a water jacket 62 provided around a pipe 23c′ which constitutes chemical liquid line 23c. A water of a room temperature or a cooled water flows within water jacket 62, the SPM liquid that flows within pipe 23c′ is cooled by the heat exchange between the SPM liquid and the water that flows through the wall surface of pipe 23c′. Cooler 61 may be configured by a Feltier element (not illustrated) provided in the outer surface of pipe 23c′. In the fourth exemplary embodiment, nozzle 60 has a single discharging port, and the SPM liquid is discharged only to the center of wafer W. Even when the configuration that cools the SPM liquid by cooler 61 is adopted, the SPM liquid may be supplied using a nozzle that has a plurality of discharging ports arranged in the radial direction of the wafer, as in the first to third exemplary embodiments.

In the first to fourth exemplary embodiments, a liquid film of deionized water may be formed on the surface of wafer W, and then, the SPM liquid (the SPM liquid which is cooled by N₂ gas, or a mixture of N₂ gas and DIW) may be supplied on the liquid film. For example, as schematically illustrated in FIG. 10, the DIW is supplied to a position at the upstream in relation to the rotation direction R of wafer W than the supply position on wafer W of the SPM liquid after mixing with N₂ gas (or the SPM liquid after mixing with N₂ gas and DIW). By doing so, the DIW forms a liquid film L on the surface of wafer W while being diffused in the radial direction of wafer W, and the SPM liquid is dropped on liquid film L. At that time, since the DIW deprives of the heat from wafer W by supplying the DIW on wafer W directly, and as a result, the reaction temperature of the SPM liquid and the resist film may be lowered to further reduce the film loss. Further, in that case, in order to suppress the increase of the temperature of the SPM liquid by the hydration heat, the temperature may be lowered, and the DIW may be supplied at a temperature equal to or less than the room temperature. In addition, although FIG. 10 illustrates a state where one nozzle 70 that discharges the N₂ gas, one nozzle 71 that discharges the SPM liquid, and one nozzle 72 discharges the DIW, the present disclosure is not limited thereto. That is, respective nozzles may be arranged randomly as long as the liquid film of the DIW is formed at the drop position of the SPM liquid after mixing with the N₂ gas (or the SPM liquid after mixing with the N₂ gas and the DIW) on wafer W.

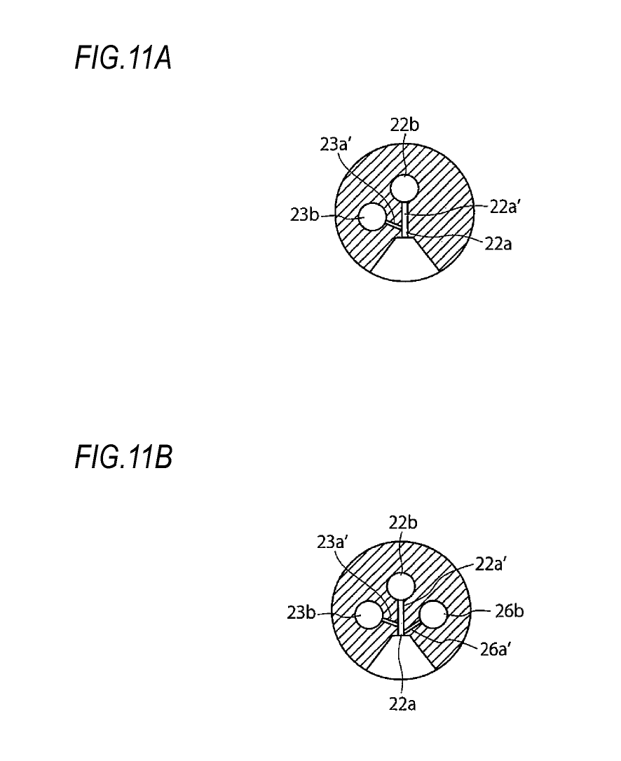

In the above-described first to three exemplary embodiments, although a cooling fluid to cool the SPM liquid (N₂ gas in first exemplary embodiment, N₂+DIW twin fluid in second exemplary embodiment, and N₂ gas and DIW in third exemplary embodiment) joins the SPM liquid discharged from chemical liquid discharging port 23a after the cooling fluid is discharged from the discharging port of the nozzle for discharging the cooling fluid (gas discharging port 22a in first and second exemplary embodiments, and gas discharging port 22a and DIW-SPM liquid discharging port in third exemplary embodiment), the present disclosure is not limited thereto. That is, the flow of the SPM liquid join the flow of the cooling fluid before the cooling fluid is discharged from the discharging port of the nozzle to discharge the cooling fluid, and then, a mixed fluid composed by mixing the SPM liquid with the cooling fluid may be discharged from the nozzle. Specifically, for example, as a modified example of the first exemplary embodiment, as illustrated in FIG. 11A, a chemical liquid discharging path 23a′ branched from chemical liquid distribution passage 23b may be connected on the way of gas discharging path 22a′ that connects gas distribution passage 22b and gas discharging port 22a. Further, as a modified example of the second exemplary embodiment, a twin fluid composed by mixing the mists (droplets) of the DIW with the N₂ gas may be supplied from (gas) distribution passage 22b as illustrated in FIG. 11A. Further, as a modified example of the third exemplary embodiment, as illustrated in FIG. 11B, chemical liquid discharging path 23a′ branched from chemical liquid distribution passage 23b and a DIW discharging port 26a′ branched from DIW distribution passage 26b may be connected on the way of gas discharging path 22a′ that connects gas distribution passage 22b and gas discharging port 22a. Even in the modified examples of the first to third exemplary embodiments as illustrated in FIGS. 11A and 11B, the SPM liquid of the first temperature in which the concentration of Caro's acid is sufficiently increased may be cooled by the cooling fluid, and thus, as in the first to third exemplary embodiments as described above, an effect that effectively separates the resist film while reducing the film loss may be obtained. Further, even in a case in which the configurations of FIGS. 11A and 11B are adopted, since the SPM liquid is discharged toward wafer W in a droplet state from gas discharging port 22a after mixing with the pressurized N₂ gas, an effect of the physical separation facilitation may also be obtained by causing the droplet to collide with the resist film. That is, it doesn't matter that the timing to mix the SPM liquid with the cooling fluid including the pressurized N₂ gas that flows toward wafer W is before or after the cooling fluid is discharged from the nozzle for discharging the cooling fluid.

Further, in the first to fourth exemplary embodiments as described above, the temperature of wafer W may be lowered by supplying a cooling fluid to the rear surface (bottom surface) of wafer W. By doing this, the reaction temperature of the SPM liquid and the resist film is lowered, and thus, the film loss may be reduced. The cooling fluid may be, for example, a DIW of a temperature less than that of the SPM liquid, and the cooling fluid may be supplied by a nozzle which is capable of being located at the downstream of wafer W.

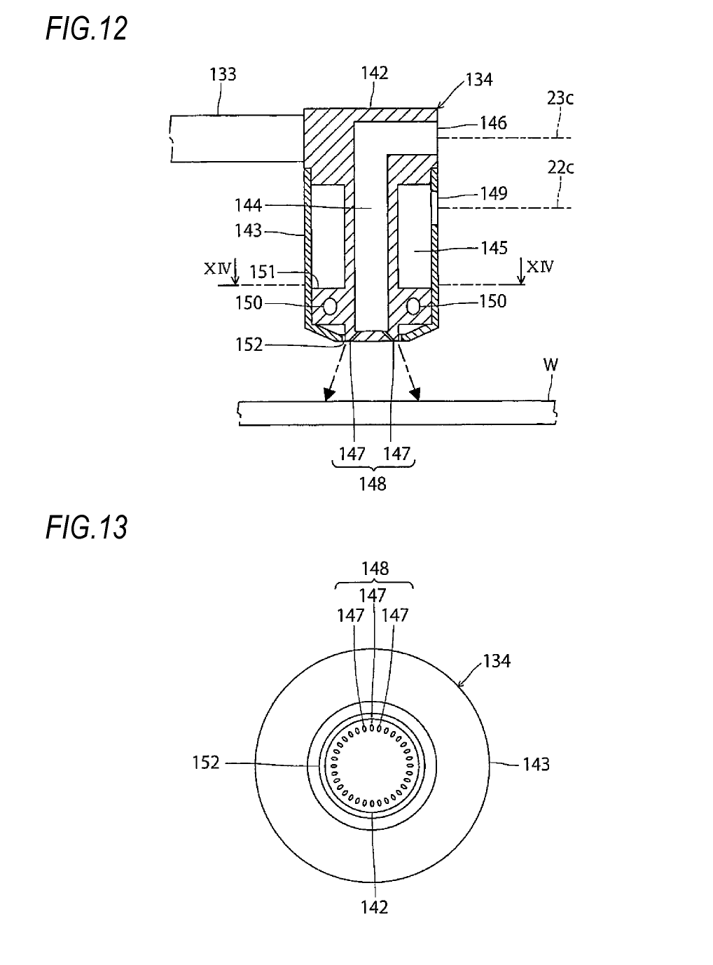

Next, a fifth exemplary embodiment will be described with reference to FIGS. 12 to 14. A twin fluid nozzle 134 used in the fifth exemplary embodiment is the same as in first rod shaped nozzle unit 20 of the first exemplary embodiment in that the droplets of the SPM liquid are formed by mixing the SPM liquid with the N₂ gas (cooling fluid) after they are discharged from their discharging ports, respectively, but an improvement to form more fine and even SPM liquid droplets is being performed.

Twin fluid nozzle 134 may be inserted into the front end of first rod shaped nozzle unit 20 illustrated in FIGS. 1 and 2. Alternatively, twin fluid nozzle 134 may be attached to the front end of an arm (indicated as a reference numeral 133 in FIG. 12) which is capable of being advanced and retreated in the radial direction of wafer W. Even in that case, twin fluid nozzle 34 may reciprocate within a range from a position right above the rotation center of wafer W to a position right above the peripheral portion of wafer W according to the advance/retreat of arm 133, and may retreat to a position outer than a place above wafer W.

As illustrated in FIGS. 12 to 14, twin fluid nozzle 134 includes a nozzle body 142, and a chemical liquid flow path 144 that causes the SPM liquid to flow is formed inside the nozzle body 142. A nozzle cover 143 is attached in the outer peripheral portion of nozzle body 142, and a gas flow path 145 that causes N₂ gas to flow is formed between an outer peripheral concave portion of nozzle body 142 and an inner peripheral surface of nozzle cover 143.

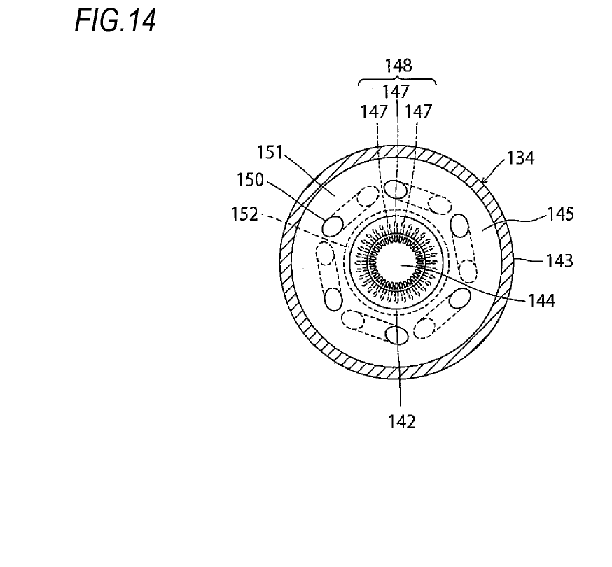

Chemical liquid line 23c (see, e.g., FIG. 1) is connected to a chemical liquid inlet 146 formed at the upper side of nozzle body 142, and the SPM liquid is supplied from chemical liquid line 23c to chemical liquid flow path 144. The lower end of nozzle body 142 is provided with a chemical liquid discharging part 148 (that is, a second nozzle part that discharges the SPM liquid). Chemical liquid discharging part 148 is constituted by a plurality of (thirty two in the present example) chemical liquid discharging ports 147 arranged at equal intervals on the same circumference. Each of chemical liquid discharging ports 147 is formed by a circular hole that is obliquely inclined downward from the center of the circumference to the outer peripheral, and therefore, twin fluid nozzle 134 may discharge the SPM liquid supplied from chemical liquid line 23c toward the outer peripheral direction slantly and downwardly in a fine stem shape from each of chemical liquid discharging ports 147. As clearly illustrated in FIG. 14, plurality of chemical liquid discharging ports 147 are radially formed from the entrance end located in the peripheral portions of chemical liquid flow path 144 toward the outlet end located in a place outer than the inner diameter of chemical liquid flow path 144. Therefore, the SPM liquid is diffused and discharged in a plurality of fine stems shape in a range wider than the inner diameter of chemical liquid flow path 144. Further, it is noted that, in order to prevent the drawing from being complicated, a cross-sectional indication (addition of a hatching) is not displayed in a cylindrical wall that partitions chemical liquid flow path 144 and gas flow path 145 in FIG. 14.

Gas line 22c (see, e.g., FIG. 1) is connected to a gas inlet 149 formed at the upper side of nozzle cover 143, and the N₂ gas is supplied from gas line 22c to gas flow path 145. In the lower side of nozzle body 142, swirl generating part 151 is provided which is constituted by a plurality of (six in here) inclined holes 150 that are inclined downwardly in the clockwise direction when viewed from the plane. A gas discharging port 152 (that is, first nozzle part that discharges N₂ gas) of an annular slit shape along a concentric circle with a diameter larger than a circle at which chemical liquid discharging ports 147 are arranged is formed between the front end of nozzle body 142 and the front end of nozzle cover 143. The N₂ gas supplied from gas line 22c to gas flow path 145 becomes a swirling flow by passing swirl generating unit 151, and then, is discharged downward from gas discharging port 152. The swirling flow may be discharged in a direction that is roughly perpendicular to the wafer W.

In twin fluid nozzle 134 with the above-described configuration, the N₂ gas is discharged downwardly from gas discharging port 152 of the annular slit shape, and the SPM liquid is discharged to the radial outside inclinedly and downwardly from plurality of chemical liquid discharging ports 147 of chemical liquid discharging part 158 toward the flow of the N₂ gas. Accordingly, the SPM liquid and the N₂ gas are collided with each other below the vicinity of chemical liquid discharging ports 147 and gas discharging port 152, the SPM liquid becomes into a smog by the N₂ gas to form the droplets of the SPM liquid, and the droplets of the SPM liquid are sprayed to the surface of wafer W. At that time, since the SPM liquid is discharged in a fine stem shape from each of plurality of chemical liquid discharging ports 147, the contact area of the SPM liquid and the N₂ gas may be increased to form a droplet with a small particle diameter evenly and effectively. Further, since the N₂ gas is discharged from gas discharging port 152 of a slit shape, the N₂ gas may be evenly collided with the SPM liquid that is radially discharged in a stem shape to generate droplets evenly.

The interval between adjacent chemical liquid discharging ports 147 is set to be large enough that two SPM liquids do not join by negative pressure that acts between the SPM liquids discharged from two adjacent chemical liquid discharging ports 147 when the SPM liquid is discharged from chemical liquid discharging ports 147. Specifically, the smallest distance between outer peripheral edges of two adjacent chemical liquid discharging ports 147 may be equal to or more than the diameter of the opening of one chemical liquid discharging port 147. Accordingly, since it may be prevented the adjacent fine stem shaped SPM liquid from being contacted and joined each other and forming a thick cylindrical shape, the droplets with small particle diameters may be generated evenly.

Further, chemical liquid discharging ports 147 and gas discharging port 152 are adjacently disposed such that SPM liquid discharged from each of chemical liquid discharging ports 147 collides with N₂ gas flow in a state the SPM liquids are not in contact with each other, and the SPM liquid collides with the N₂ gas discharged from gas discharging port 152 right after the SPM liquid is discharged from chemical liquid discharging ports 147. Accordingly, the SPM liquid in a plurality of fine stem state collides with the N₂ gas, and thus, the droplets with small particle diameters may be generated evenly. Further, when a deviation exists in the discharging angle of the SPM liquid from each chemical liquid discharging port 147, it is apprehended that a deviation in the height at which the SPM liquid and the N₂ gas are collided each other generated. However, the deviation of the colliding height may be suppressed by adjacently locating chemical liquid discharging ports 147 to gas discharging port 152. By doing so, the deviation may not be generated in the colliding condition of the SPM liquid and the N₂ gas, thereby evenly generating the droplets of the SPM liquid.

According to the fifth exemplary embodiment, the same action and effect as in the first exemplary embodiment may be obtained. Further, according to the fifth exemplary embodiment, since the droplets of the SPM liquid may be finely and evenly formed as compared to the first exemplary embodiment, the SPM liquid may be further effectively cooled. Further, the separation facilitation effect of the resist film by the high physical energy that the twin fluid has may be further increased.

In addition, as for a sixth exemplary embodiment, a fluid line (gas line 22c) as illustrated in FIG. 6 is connected to gas inlet 149 of twin fluid nozzle 134 as illustrated in FIGS. 12 to 14, a twin fluid composed by mixing the droplets of the DIW with the N₂ gas may flow in a fluid flow path of twin fluid nozzle 134 (a portion corresponding to gas flow path 145 in FIGS. 12 to 14), and the twin fluid may be discharged from gas discharging port 152. As in the fifth exemplary embodiment, the SPM liquid is supplied to chemical liquid flow path 144 from chemical liquid line 23c, and the SPM liquid is discharged from chemical liquid discharging ports 147. The SPM liquid discharged from chemical liquid discharging ports 147 collides with the twin fluid composed by mixing the droplets of the DIW with the N₂ gas, and thus, the SPM liquid becomes a fine droplet and is supplied to wafer W. According to the sixth exemplary embodiment, the same action and effect as in the second exemplary embodiment may be obtained. Further, according to the sixth exemplary embodiment, since the droplets of the SPM liquid may be finely and evenly formed as compared to the second exemplary embodiment, the SPM liquid may be further effectively cooled. Further, the separation facilitation effect of the resist film by the high physical energy that the twin fluid has may be further increased.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A substrate processing method comprising:
generating an SPM liquid of a first temperature that contains Caro's acid having a separation effect of a resist film formed on the surface of a substrate by mixing heated sulfuric acid with hydrogen peroxide;
cooling the SPM liquid to a second temperature at which a film loss-reduction effect occurs; and
applying the SPM liquid of the second temperature to the resist film thereby separating the resist film.

2. The substrate processing method of claim 1, wherein the cooling step is performed by mixing the SPM liquid with N₂ gas that flows toward the substrate.

3. The substrate processing method of claim 1, wherein the cooling step is performed by mixing deionized water and the SPM liquid with N₂ gas that flows toward the substrate.

4. The substrate processing method of claim 1, wherein the cooling step is performed by mixing the SPM liquid with a twin fluid that is composed by mixing droplets of deionized water with N₂ gas and flows toward the substrate.

5. The substrate processing method of claim 1, wherein the cooling step is performed using a cooler provided in a pipe between a position where the sulfuric acid and the hydrogen peroxide are mixed and a nozzle that discharges the SPM liquid to the substrate.

6. The substrate processing method of claim 2, wherein the SPM liquid cooled to the second temperature is supplied to the substrate in a state where a liquid film of water is formed on the surface of the substrate.

7. A substrate processing apparatus that removes a resist film formed on the surface of a substrate, comprising:
a substrate holding unit configured to hold the substrate;
a sulfuric acid supply unit configured to supply sulfuric acid;
a hydrogen peroxide supply unit configured to supply hydrogen peroxide;
a mixing unit configured to mix the sulfuric acid supplied from the sulfuric acid supply unit with the hydrogen peroxide supplied from the hydrogen peroxide supply unit to generate an SPM liquid;
an SPM liquid supply unit configured to supply the SPM liquid to the substrate; and
a cooling unit configured to cool the SPM liquid of a first temperature which is flown out from the mixing unit and contains Caro's acid having a separation effect of the resist film to a second temperature at which a reduction effect of film loss occurs before the SPM liquid reaches the substrate.

8. The substrate processing apparatus of claim 7, wherein the cooling unit includes a cooling fluid discharging unit configured to discharge cooling fluid that is capable of cooling the SPM liquid toward the substrate, and
the SPM liquid supply unit includes a joining unit configured to cause the flow of the SPM liquid to join the flow of the cooling fluid before the cooling fluid reaches the surface of the substrate.

9. The substrate processing apparatus of claim 8, wherein the joining unit that causes the flow of the SPM liquid to join the flow of the cooling fluid includes a chemical liquid nozzle configured to discharge the SPM liquid toward the substrate,
the cooling fluid discharging unit includes a gas nozzle configured to discharge N₂ gas toward the substrate, and
the gas nozzle is configured such that the N₂ gas discharged from the gas nozzle is mixed with the SPM liquid discharged from the chemical liquid nozzle before the SPM liquid reaches the substrate.

10. The substrate processing apparatus of claim 8, wherein the joining unit that causes the flow of the SPM liquid to join the flow of the cooling fluid includes a chemical liquid nozzle configured to discharge the SPM liquid toward the substrate,
the cooling fluid discharging unit includes a gas nozzle configured to discharge N₂ gas toward the substrate and a deionized water nozzle configured to discharge deionized water toward the substrate,
the gas nozzle is configured such that the N₂ gas discharged from the gas nozzle is mixed with the SPM liquid discharged from the chemical liquid nozzle before the SPM liquid reaches the substrate, and
the deionized water nozzle is configured such that the deionized water discharged from the deionized water nozzle is mixed with the SPM liquid discharged from the chemical liquid nozzle before the SPM liquid reaches the substrate.

11. The substrate processing apparatus of claim 8, wherein the joining unit that causes the flow of the SPM liquid to join the flow of the cooling fluid includes a chemical liquid nozzle configured to supply the SPM liquid toward the substrate,
the cooling fluid discharging unit includes a twin fluid nozzle configured to discharge twin fluid composed by mixing the droplets of the deionized water with the N₂ gas toward the substrate, and
the twin fluid nozzle is configured such that the twin fluid discharged from the twin fluid nozzle is mixed with the SPM liquid discharged from the chemical liquid nozzle before the SPM liquid reaches the substrate.

12. The substrate processing apparatus of claim 7, wherein the SPM liquid supply unit includes a chemical liquid nozzle configured to supply the SPM liquid toward the substrate, and
the cooling unit includes a cooler provided in the pipe that causes the SPM liquid to flow from the mixing unit to the chemical liquid nozzle.

13. The substrate processing apparatus of claim 7, further comprising:
a deionized water nozzle configured to supply deionized water to the substrate, and
a control unit configured to control the operations of the substrate processing apparatus such that, when the deionized water is supplied from the deionized water nozzle to form a liquid film of the deionized water on the surface of the substrate, the SPM liquid supplied by the SPM liquid supply unit and cooled by the cooling unit is discharged toward the substrate.
